(19) United States
(12) Patent Application Publication
(10) Pub. No.: US 2019/0252568 A1
(43) Pub. Date: Aug. 15, 2019

(54) HIGH-TEMPERATURE SEMICONDUCTOR BARRIER REGIONS

(71) Applicant: SOLAR JUNCTION CORPORATION, San Jose, CA (US)

(72) Inventors: TING LIU, SAN JOSE, CA (US); FERRAN SUAREZ, CHANDLER, AZ (US); ARSEN SUKIASYAN, PLAINSBORO, NJ (US); AYMERIC MAROS, SAN FRANCISCO, CA (US)

(21) Appl. No.: 16/276,432

(22) Filed: Feb. 14, 2019

Related U.S. Application Data
(60) Provisional application No. 62/630,937, filed on Feb. 15, 2018.

(51) Int. Cl. H01L 31/078; H01L 31/0352; H01L 31/18

(52) U.S. Cl. CPC H01L 31/078; H01L 31/18; H01L 31/0352

(57) ABSTRACT

Semiconductor devices having a high-temperature barrier layer between a III-V material and an underlying substrate are disclosed. The high-temperature barrier layer can minimize or prevent diffusion of arsenic and phosphorous from an overlying layer into the underlying substrate. Dilute nitride-containing multijunction photovoltaic cells incorporating a high-temperature barrier layer exhibit high efficiency.

This application claims the benefit under 35 U.S.C. § 119(e) of U.S. Provisional Application No. 62/630,937 filed on Feb. 15, 2018, which is incorporated by reference in its entirety.

### FIELD

The present invention relates to semiconductor devices having a high-temperature barrier region between a semiconductor layer and an underlying substrate where the high-temperature barrier region minimizes diffusion of group V elements from the semiconductor layer into the underlying substrate. Dilute nitride-containing multijunction photovoltaic cells incorporating a high-temperature barrier region exhibit high efficiency.

### BACKGROUND

The deposition of epitaxial layers to provide III-V optoelectronic devices, such as multijunction photovoltaic cells and light-emitting diodes (LEDs), on group IV substrates is known. The electronic and optical properties of such devices are being studied extensively and the correlation between these properties and the characteristics of the substrate-epilayer interface is receiving great attention. The reason for the attention given to the substrate-epilayer interface is that the performance of these devices is determined, in part, by the quality of this interface.

When a III-V material such as GaAs is epitaxially deposited on a group IV substrate such as germanium, the formation of the appropriate atomic layer sequence of the group III and group V layers is not readily established. The group IV sites (germanium atoms) can bond to either group III or to group V atoms. In practice, some regions of the group IV substrate will bond to group III atoms and other substrate regions will bond to group V atoms. The boundary regions between these different growth areas give rise to structural defects, such as anti-phase domains, which adversely affect the performance of a device.

To curtail some of these structural defects, group IV substrates are usually vicinal substrates with an off-cut angle ranging from 0° to 15°. These vicinal substrates provide terraces and step edges where the atoms can bond with different configurations, thus providing greater order in the growth process.

In devices such as, for example, photovoltaic cells having III-V alloys epitaxially deposited on a group IV substrate, it can be desirable to create part of the device in the group IV substrate by diffusing, for example, a group V species into the group IV substrate. As an example, for photovoltaic cells, if a group V element is diffused into a p-type germanium substrate, an n-type emitter region is formed, giving rise to an n-p junction. This n-p junction becomes photo-active and can be part of a single junction or a junction of a multijunction solar cell. However, when depositing the III-V compound at typical process temperatures (600° C. to 700° C.) on the active germanium junction, the group V element of the III-V compound tends to diffuse, with little control, into the germanium junction, thereby making formation of a predictable n-p junction difficult.

Additional doping with a group V element introduces an interfering electric field to the built-in electric field at the emitter-base interface of the germanium junction. The minority carriers generated by the photovoltaic effect in the junction structure are affected by this additional electric field. The presence of an unintentional doping profile across a junction base layer can impede the movement of minority carriers to the front of the junction, resulting in low recombination velocity and poor minority carrier collection.

In cases involving germanium substrates with a pre-existing n-p junction, as can be the case in hetero-integration of III-V optoelectronics on germanium, SiGe and SiC electronic circuits, the deposition of an overlying III-V layer can modify the doping profile of the pre-existing n-p junction resulting in suboptimal performance of the n-p junction, and the device as a whole. The doping level is a result of the competition between in-junction diffusion and dopant loss. Consequently, the electrical characteristics of the interface are not easily controllable. In such situations, it can be difficult, if not impossible, to achieve and maintain a desired doping profile in the germanium and thereby maintain desired electrical characteristics of the n-p junction at the substrate interface. Such electrical characteristics include, in the case of photovoltaic cells, the open circuit voltage (Voc). Furthermore, group IV atoms will diffuse from the substrate into the adjacent III-V layers. Hence, overlying materials within the initial 0.5 micron to 1 micron of the III-V layer interface can become highly doped with the group IV element when the excessive diffusion of group IV atoms is not curtailed, for example, using suitable barrier materials and/or processing conditions. Group IV atoms such as silicon and germanium are, at moderate concentrations, typically n-type dopants in III-V semiconductor material. However, due to their amphoteric nature these atoms can cause a large degree of compensation (combined incorporation of n- and p-type impurities) when incorporated at concentrations higher than 2×10¹⁸ cm³, which can lead to a strong deterioration of electrical and optical properties of the host semiconductor layer.

In the prior art (FIGS. 1A-1C), semiconductors with an active germanium substrate relied on an overlying nucleation layer as a source of group V dopants, which diffused into the underlying p-type bulk germanium to form of a n-p germanium junction. A group V dopant includes nitrogen, phosphorous, arsenic, antimony, and bismuth. In some examples, phosphorus atoms from an overlying InGaP or InP nucleation layer were used to intentionally shape the doping profile of the n-type, upper region of the germanium substrate. Typically, a GaAs buffer layer was deposited over the nucleation layer. A well-defined dopant profile is critical for the germanium junction to function with optimum efficiency. It appears that extreme conditions (e.g., temperature, deposition rate and group V overpressure) for the epitaxial growth of a nucleation layer were required to obtain devices with suitable morphology and a low defect density. Under these conditions, inadvertent diffusion of dopants (e.g., arsenic from the GaAs buffer layer and phosphorus from the InGaP/InP) is unavoidable and difficult to control. This gives rise to complications in designing and crafting a specific dopant diffusion profile for optimum junction performance. In some examples, phosphorus atoms had a higher concentration than arsenic atoms in the n-type, upper region of germanium, while the inverse was true for others. Typically, an intentional two-group V dopant diffusion profile of arsenic and phosphorous is present in the n-type, upper region of germanium.

There have been attempts to control the electrical characteristics of germanium n-p junction by sandwiching a binary compound nucleation layer between a p-type germanium substrate and a buffer layer (FIG. 1C). Presumably, group V dopant diffusion is inversely proportional to the thickness of the nucleation layer. A nucleation layer with an appropriate thickness was used to modulate phosphorus diffusion from the AlInGaP, InGaP, or AlInP buffer layer into germanium. The conditions disclosed in the prior art are incompatible with the thermal treatment requirements of dilute nitride systems. Specifically, decreasing performance of a multijunction photovoltaic cell, such as Voc, fill factor, Jsc and efficiency, correlates with increasing nucleation layer thickness.

Dilute nitrides are a class of III-V alloy materials (alloys having one or more elements from Group III in the periodic table along with one or more elements from Group V in the periodic table) with small fractions (less than 5 atomic percent, for example) of nitrogen. Dilute nitrides are of interest because they can be lattice-matched to different substrates, including GaAs and germanium. Although metamorphic structures for III-V multijunction photovoltaic cells can be used, lattice-matched dilute nitride structures are preferred due to band gap tunability and lattice constant matching, making dilute nitrides ideal for integration into multijunction photovoltaic cells with substantial efficiency improvements. Dilute nitrides have proven performance reliability and require less semiconductor material in manufacturing. The high efficiencies of dilute nitride photovoltaic cells make them attractive for terrestrial concentrating photovoltaic systems and for photovoltaic systems designed to operate in space. Significantly, thermal treatment is an essential and unique step in the fabrication of dilute nitride photovoltaic cells, which is not required for conventional semiconductors. A thermal load is required to ameliorate structure defects within the dilute nitride material. Unfortunately, the thermal treatment useful for improving dilute nitride material quality, also negatively impacts other semiconductor layers within a heteroepitaxial stack, such as the performance of a germanium bottom junction.

Nucleation layers in the prior art were not chosen or designed to withstand thermal treatments routinely used in the growth and fabrication of high-performance dilute nitride devices. In general, a thermal treatment for dilute nitrides involves exposing the dilute nitride to a temperature within a range from 600° C. to 900° C. for a duration from 5 seconds to 5 hours, such as from 5 seconds to 3 hours. In some cases, there are no limits for temperature and time. In some cases, the temperature is applied during the growth of the dilute nitride material. Table 1 summarizes typical thermal treatment parameters by deposition method and thermal annealing condition.

TABLE 1
Thermal treatment methods, temperatures and times.

| Method | MBE¹ | MOCVD¹ | RTA¹ | Oven |
|---|---|---|---|---|
| Time | 2-8 hours | 0.5-1 hour | 0.1-10 minutes | Any duration |
| Temperature | 600° C.- | 630° C.- | 600° C.- | Any temperature |
| | 650° C. | 700° C. | 900° C. | |

¹Molecular beam epitaxy (MBE) metal-organic chemical vapor deposition (MOCVD), rapid thermal annealing (RTA).

Prior art phosphide-based nucleation layers are disclosed in U.S. Pat. No. 6,380,601 B1 and in U.S. Pat. No. 7,339,109 B2, but these were not applied to dilute-nitride-based multijunction cells. Garcia et al., in “Degradation of subcells and tunnel junctions during growth of GaInP/Ga(In)As/GaNAsSb/Ge 4-junction solar cells”, Prog Photovolt Res Appl. 2017; 1-9 discloses that when a GaInP nucleation layer is used in a device containing a dilute nitride layer, the subsequent thermal loads associated with growth and processing of the dilute nitride materials to form the overall device results in degradation of the Ge junction performance in the multijunction solar cell. A 15% reduction in short circuit current density Jsc and a 50 mV decrease in open circuit voltage Voc, under a 1-sun illumination was observed, which was attributed in part to diffusion of indium from the GaInP barrier layer into the Ge subcell.

Therefore, new diffusion-control layers able to withstand high-temperature processing such as used in dilute nitride epitaxial processing are needed. A barrier region able to withstand such treatment is referred to a high-temperature barrier region, because it is able to maintain functionality, and produce desired device results, under high-temperature processing and/or operating conditions. Desired results include devices with acceptable, if not improved, optical and electrical interface properties, due to suitable morphology and a well-defined dopant diffusion profile(s) in the materials on either side of the high-temperature barrier region.

### SUMMARY

According to the present invention, semiconductor structures comprise: a first semiconductor layer, wherein the first semiconductor layer comprises a group V element; a high-temperature barrier region underlying the first semiconductor layer, wherein the high-temperature barrier region comprises one or more barrier layers, wherein at least one of the barrier layers comprises an indium-free barrier layer or an aluminum-containing barrier layer; and a second semiconductor layer underlying the high-temperature barrier region.

According to the present invention, semiconductor devices comprise the semiconductor structure according to the present invention.

According to the present invention, multijunction photovoltaic cells comprise the semiconductor structure according to the present invention.

According to the present invention, photovoltaic modules comprise the multijunction photovoltaic cell according to the present invention.

According to the present invention, power systems comprise the photovoltaic module according to the present invention.

According to the present invention, methods of fabricating a semiconductor structure comprise: providing a first semiconductor layer; depositing a high-temperature barrier region on the first semiconductor layer, wherein the high-temperature barrier region comprises one or more barrier layers, wherein at least one of the barrier layers comprises an indium-free barrier layer, an aluminum-containing barrier layer, or a combination thereof; and depositing a group V-containing layer on the barrier region to form the semiconductor structure.

According to the present invention, methods of fabricating a semiconductor device comprise: providing the semiconductor structure according to the present invention; and depositing at least one third semiconductor layer on the second semiconductor layer to form the semiconductor device.

According to the present invention, multijunction photovoltaic cells comprise an n-p (Sn,Si)Ge junction comprising an arsenic-doped n-type region; an high-temperature barrier region overlying the n-type region of the n-p (Sn,Si)Ge junction, wherein the high-temperature barrier region comprises one or more barrier layers, wherein at least one of the barrier layers comprises an indium-free barrier layer, an aluminum-containing barrier layer, or a combination thereof; an (In)GaAs layer overlying the high-temperature barrier region; and at least one dilute nitride junction overlying the (In)GaAs layer.

According to the present invention, photovoltaic modules comprise the multijunction photovoltaic cell according to the present invention.

According to the present invention, power systems comprise the photovoltaic module according to the present invention.

### BRIEF DESCRIPTION OF THE DRAWINGS

Those skilled in the art will understand that the drawings described herein are for illustration purposes only. The drawings are not intended to limit the scope of the present disclosure.

FIGS. 1A-1C show prior art semiconductor structures including a buffer layer, a phosphide or nucleation layer, a n-doped germanium substrate region, and a p-doped germanium substrate region.

FIG. 2A shows an example of a semiconductor structure including a buffer layer, a high-temperature barrier region, and a n-doped germanium substrate or a p-doped germanium substrate, according to the present invention.

FIG. 2B shows an example of a semiconductor structure including a buffer layer, a high-temperature barrier region including an overlayer and an indium-free barrier layer, and a n-doped germanium substrate region or a p-doped germanium substrate, according to the present invention.

FIGS. 3-6 show examples of process flow steps for preparing a semiconductor structure according to the present invention.

FIGS. 7A-7C show examples of junction compositions for a 3J (3-junction), a 4J (4-junction), and a 5J (5-junction) multijunction photovoltaic cell, respectively.

FIG. 8 shows an example of the functional layer structure of a 4J multijunction photovoltaic cell according to the present invention.

FIG. 9A shows an example of compositions and associated functions of certain layers that may be present in a 4J multijunction photovoltaic cell comprising AlInGaP/(Al,In)GaAs/GaInNAsSb/Ge.

FIG. 9B shows an example of compositions and functions of certain layers that may be present in a 4J multijunction photovoltaic cell comprising AlInGaP/(Al,In)GaAs/GaInNAsSb/Ge.

FIG. 10 shows a surface scan image for a wafer using an AlP/InAlP barrier region.

FIG. 11 shows properties of a germanium junction with an overlying InGaP barrier layer or with an overlying InAlP barrier layer separating an InGaAs layer from the underlying germanium junction, with and without thermal treatment.

FIG. 12 shows properties of a germanium junction with different thicknesses of an InAlP barrier layer separating an InGaAs layer from the underlying germanium junction, with and without thermal treatment.

FIG. 13 shows properties of a germanium junction with an AlP/InAlP barrier region separating an InGaAs layer from the underlying germanium junction, with and without thermal treatment.

FIG. 14 shows the efficiency as a function of irradiation wavelength for a germanium junction with and without a high-temperature barrier region and with and without thermal treatment.

FIG. 15 shows the LIV of a 4J multijunction photovoltaic cell fabricated with an InGaP nucleation layer or a high-temperature InAlP barrier layer, respectively.

FIG. 16A shows the efficiency as a function of irradiation wavelength for each of the junctions of a 4J multijunction photovoltaic cell with a high-temperature barrier region and following high-temperature annealing.

FIG. 16B shows the short circuit current density Jsc for each of the junctions of a 4J multijunction photovoltaic cell with an InGaP nucleation layer or a high-temperature InAlP barrier layer following high-temperature annealing.

FIG. 17A shows an electron micrograph of an example of a barrier region according to the invention.

FIG. 17B shows an electron micrograph of an example of a barrier region according to the invention.

FIG. 17C shows an electron micrograph of an example of a barrier region according to the invention.

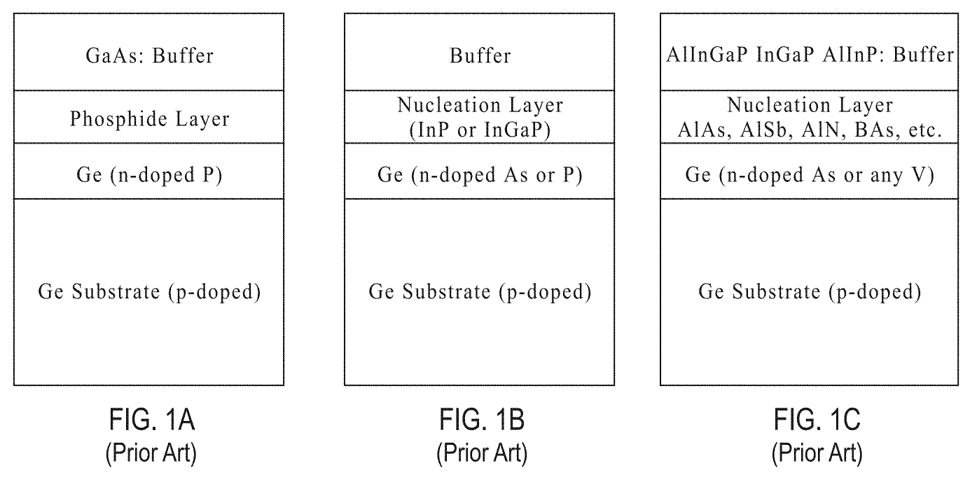

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized, and structural, logical, and electrical changes may be made without departing from the scope of the invention. The various embodiments disclosed herein are not necessarily mutually exclusive, as some disclosed embodiments may be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

The term “pseudomorphically strained” as used herein means that layers made of different materials with a lattice parameter difference can be grown on top of other lattice matched or strained layers without generating misfit dislocations. The lattice parameters can differ, for example, by up to +/−2% or, by up to +/−1%. The lattice parameters can differ, for example, by up to +/−0.5% or by up to +/−0.2%.

The devices and methods of the present disclosure facilitate the fabrication of high quality electronic and optoelectronic devices, including multijunction photovoltaic cells, power converters and photodetectors, having a high-temperature barrier alloy overlying a group IV substrate. The disclosure teaches the fabricating of devices with controlled doping profiles of group III and/or group V elements into the group IV substrate and high-performance device characteristics. The use of a high-temperature barrier region provided by the present disclosure attenuates the diffusion of atoms from overlying semiconductor layers into a group IV substrate can render the semiconductor device more robust to thermal processing and in particular to high-temperature thermal processing. The use of a high-temperature barrier region can, for example, modify, attenuate, and/or minimize the diffusion of group V atoms, such as for example, arsenic atoms, or group III atoms, such as for example, indium atoms, from overlying semiconductor layers into an underlying material layer such as a germanium active junction, that would otherwise alter a desired doping profile within an active germanium junction, and thereby degrade the performance of the active germanium junction and the overall device. The use of a high-temperature barrier region provided by the present disclosure can also attenuate the diffusion of atoms from a group IV substrate, such as for example germanium atoms, into the overlying III-V semiconductor layers.

A high-temperature barrier region provided by the present disclosure can comprise one or more barrier layers. For example, a high-temperature barrier region can comprise one barrier layer, two barrier layers, three barrier layers, or more than three barrier layers. Each barrier layer can be characterized by a different nominal elemental composition, different deposition parameters, or a combination thereof. A barrier layer can comprise the same elements as another barrier layer but with a different elemental composition. Each barrier layer of the barrier region can be lattice-matched to the underlying layer such as lattice-matched to an underlying germanium layer. For example, each barrier layer can be lattice-matched to Ge within, for example, +/−1,500 arcsec or within +/−1,000 arcsec of X-ray peak diffraction separation. The composition of a barrier layer can be selected to match or closely match the lattice constant of the underlying layer such as an underlying germanium layer. For example, the lattice constant of a barrier layer can be within ±0.6%, within ±0.4% or within ±0.2% that of the underlying layer.

A high-temperature barrier region can comprise an indium-free barrier layer comprising AlP, GaP, AlGaP, AlPSb, GaPSb or AlGaPSb. An indium-free barrier layer can comprise, for example, less than 5E18 cm⁻³ indium or less than 1E18 cm⁻³ indium.

A high-temperature barrier region comprising an indium-free barrier layer can comprise an overlying barrier layer comprising, for example, InAlP, InGaP InAlPSb, InAlPBi, InAlPSbBi, AlInGaP, AlInGaPSb, AlInGaPBi, AlInGaPSbBi, AlP, GaP. AlGaP, AlPSb, GaPSb, AlGaPSb, AlPBi, AlPSbBi, AlAsSb, AlAsBi, AlAsSbBi, AlN, AlNSb, AlNBi, or AlNSbBi. For example, a barrier layer overlying an indium-free barrier layer can comprise InGaAlPSb, wherein the InGaAlPSb is InGaAlP_{1-zx}Sb_{z}, with, for example, 0≤z≤0.38, 0≤z≤0.30, or 0≤z≤0.20.

A high-temperature barrier region can comprise an aluminum-containing barrier layer comprising, for example, InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi. For example, a high-temperature barrier region can comprise InAlPSb, wherein the InAlPSb is InAlP_{1-z}Sb_{z}, with, for example 0≤z≤0.34, 0≤z≤0.30, or 0≤z≤0.20.

A high-temperature barrier region is deposited directly on the germanium (group IV) substrate. Thus, the high-temperature barrier region can also serve as a nucleation layer for subsequent semiconductor growth. A nucleation layer can be used to planarize the surface for subsequent semiconductor growth and can be used to minimize propagation of defects into overlying semiconductor layers.

A substrate can be a germanium substrate such as a (Sn,Si)Ge substrate, and includes, Ge, SnGe, SiGe, and SnSiGe. Other substrates can be used where the lattice constant is engineered to approximately match that of Ge, such as a buffered silicon substrate. Examples of buffers that can be grown on silicon to allow growth of germanium include SiGeSn, and rare-earth oxides (REOs).

A semiconductor layer can be lattice matched to one or more of the other semiconductor layers in the structure. “Lattice matched” refers to semiconductor layers in which the in-plane lattice constants of adjoining materials in their fully relaxed states differ by less than 0.6% when the materials are present in thicknesses greater than 100 nm. A junction of a photovoltaic cell that is latticed matched to another junction of the photovoltaic cell means that all material layers in the junction that are present in thicknesses greater than 100 nm have in-plane lattice constants in their fully relaxed states that differ by less than 0.6%. For example, in a photovoltaic junction comprising a back surface field, a base, an emitter, and a front surface field, each of the layers having a thickness greater than 100 nm can be lattice matched. In an alternative meaning, substantially lattice matched refers to the strain. As such, base layers can have a strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. Strain refers to compressive strain and/or to tensile strain.

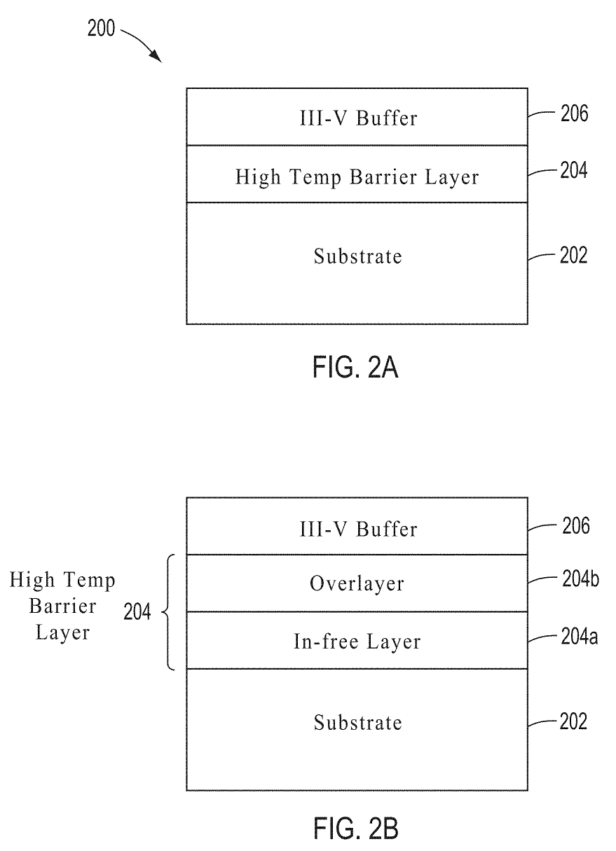

FIG. 2A shows a schematic of an example of a semiconductor structure 200 according to the present invention. Structure 200 comprises a substrate 202, a high-temperature barrier region 204 overlying the substrate 202, and a III-V buffer layer 206 overlying the high-temperature barrier region. For simplicity, each layer is shown as a single layer. However, it will be understood that each layer can include one or more layers with differing compositions, thicknesses, and/or doping levels and/or doping profiles.

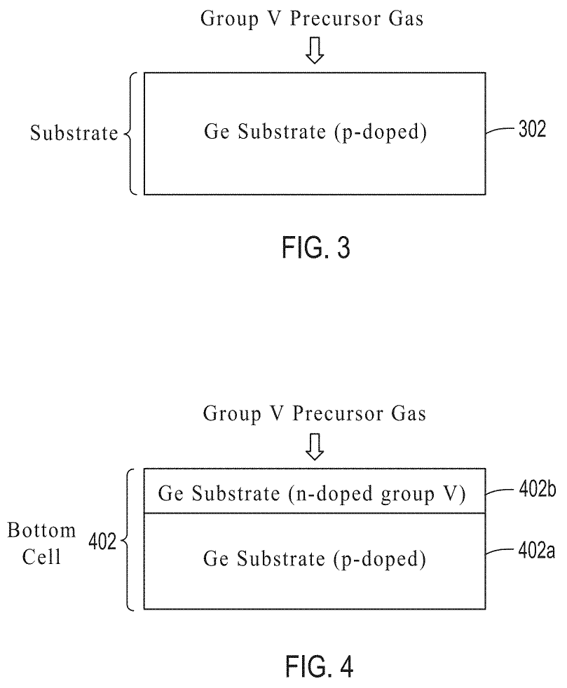

The substrate 202 can have a lattice constant that matches or nearly matches the lattice constant of Ge. The substrate can be Ge. Substrate 202 can include one or more layers, for example a Si layer having an overlying SiGeSn buffer layer that is engineered to have a lattice constant that matches or nearly matches the lattice constant of Ge. Substrate 202 can have any suitable thickness. A substrate 202 can have a p-type doped region and an n-type doped region, where the n-typed doped region is adjacent the high-temperature barrier region. As is described in FIGS. 3-4, an n-type region may be formed at the top of substrate 202 so as to form an n-p junction. The n-p junction can serve as an active germanium junction comprising a lower region that is p-doped, and an upper/emitter region that is n-doped with a dopant such as arsenic. A n-p Ge junction can serve as the “bottom cell” of a multijunction photovoltaic device. A substrate may be doped n-type, or may be a semi-insulating, such as a Si substrate.

Referring to FIG. 2A, high-temperature barrier region 204 overlies substrate 202. High-temperature barrier region 204 can comprise an indium-free barrier layer. An indium-free barrier layer can comprise, for example, AlP, GaP, AlGaP, AlPSb, GaPSb, or AlGaPSb. Where the indium-free barrier layer comprises AlP, GaP or AlGaP, the indium-free barrier layer can have a thickness, for example, less than about 1.3 nm or less than or equal to five monolayers. For example, an indium-free barrier layer can have a thickness from 0.5 nm to 6 nm, from 1 nm to 4 nm, or from 1 nm to 2 nm.] An indium-free barrier layer may not form at least one complete monolayer or may have a thickness that varies due to incomplete coverage. Buffer layer 206 can fill in any incomplete coverage of the indium-free barrier layer and can produce a smooth surface for further epitaxial growth. Where the indium-free barrier layer comprises AlPSb, GaPSb, or AlGaPSb, the indium-free barrier layer can have a thickness, for example, less than about 200 nm, less than 100 nm or less than 50 nm, such as from 10 nm to 200 nm, from 20 nm to 150 nm, or from 20 nm to 100 nm. A high-temperature barrier region 204 can have a thickness, for example, from 2 nm to 20 nm, or from 4 nm to 20 nm.

A high-temperature barrier region 204 can comprise an aluminum-containing barrier layer. An aluminum-containing barrier layer can comprise InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi. A high-temperature barrier region 204 can have a thickness less than about 200 nm, such as less than 100 nm or less than 50 nm. A high-temperature barrier region 204 can have a thickness from 2 nm to 20 nm. A high-temperature barrier region 204 can have a thickness from 4 nm to 10 nm.

FIG. 2B shows a schematic of an example of a semiconductor structure 200 according to the invention. Structure 200 comprises a substrate 202, a high-temperature barrier region 204 comprising an indium-free barrier layer 204a and an overlying barrier layer 204b, and a III-V buffer layer 206. For simplicity, each layer is shown as a single layer. However, it will be understood that each layer can include one or more layers with differing compositions, thicknesses and/or doping levels. An indium-free barrier layer can comprise AlP, GaP or AlGaP, and can have a thickness less than about 1.3 nm or less than or equal to five monolayers. An indium-free barrier layer 204a can form at least one complete monolayer. An indium-free barrier layer may not form at least one complete monolayer or may have a thickness that varies due to incomplete coverage of a layer. Overlying barrier layer 204b and/or buffer layer 206 can fill in any incomplete coverage and can produce a smooth surface for further epitaxial growth. High-temperature barrier region 204 can have a thickness, for example, from 0.25 nm to 200 nm, where indium-free barrier layer 204a can have a thickness less than about 1.3 nm or less than or equal to five monolayers, and overlying barrier layer 204b has a thickness less than about 200 nm. An overlying barrier layer 204b is from 2 nm to 20 nm thick. An overlying barrier layer 204b can be from 4 nm to 10 nm thick. Overlying barrier layer 204b can be lattice matched or pseudomorphically strained to the substrate 202. Overlying barrier layer 204b can comprise a composition that is lattice matched to a substrate to within +/−1500 arcsec of X-ray peak diffraction separation (between substrate and overlayer). An overlying barrier layer 204b can be InAlP. An overlying barrier layer 204b can be InGaP. An overlying barrier layer 204b can be an InₓGa_{y}Al_{1-y-z}P_{1-z}Sb_{z} layer with 0≤x≤1, and 0≤z≤0.38, or 0≤z≤0.38. Overlying barrier layer 204b can comprise InAlP, InGaP, InAlPSb, InAlPBi, InAlPSbBi, AlInGaP, AlInGaPSb, AlInGaPBi, AlInGaPSbBi, AlP, GaP, AlGaP, AlPSb, GaPSb, AlGaPSb, AlPBi, AlPSbBi, AlAsSb, AlAsBi, AlAsSbBi, AlN, AlNSb, AlNBi, or AlNSbBi.

The overlying barrier layer can be grown as a (bulk) random alloy, or as a digital alloy superlattice, having an average composition, where the average composition is achieved through thin layers with different compositions. As understood by those skilled in the art, a digital alloy is an alloy with an average composition that is grown using two or more different semiconductor components. The average composition of the digital alloy depends on the thickness and composition of each of the constituent layer types used to form the digital alloy. The digital alloy layers are typically thin, of the order of 10 Angstroms to 100 Angstroms, so that the resulting material has the properties of the average composition and not of the individual layers constituting the alloy. For example, a digital alloy of alternating layers of InAlP and InGaP produces InGaAlP, and a digital alloy of alternating layers of InP and AlP produces InAlP. The composition of the overlying barrier layer may be graded, having different regions with different compositions. For example, an overlying barrier layer may comprise an InAlP layer and/or an InGaP layer. The overlying barrier layer may comprise more than one InₓGa_{y}Al_{1-y-z}P_{1-z}Sb_{z} layer (with 0≤x≤1, and 0≤z≤0.38, or 0≤z≤0.38), where the values for x, y, and z may differ for each individual layer

High-temperature barrier region 204 can prevent or attenuate group V (e.g., arsenic) diffusion or group III diffusion (e.g., indium) from an overlying semiconductor layer such as an (In)GaAs buffer layer into the underlying substrate 202. With respect to a multijunction photovoltaic cell, high-temperature barrier region 204 functions to maintain a predefined arsenic diffusion profile in the upper/emitter region of germanium, thereby maintaining the intended electrical properties of the germanium junction (bottom cell). High-temperature barrier region 204 can be used in multijunction photovoltaic cells, in other optoelectronic devices, such as in light-emitting diodes (LEDs), photodetectors and LASERS, and can also be used in electronic devices where III-V materials are integrated with group-IV substrates. A high-temperature barrier region can be used in semiconductor devices that are exposed to high-temperature processing or high use temperatures. High-temperature refers to a continuous or intermittent temperature that can cause diffusion of a group III or a group V element into an underlying layer, or a group IV element into an overlying layer. The rate of diffusion depends on the temperature and time. For example, during processing a semiconductor can be exposed to a temperature from 600° C. to 900° C. for from 5 minutes to 3 hours. In operation, a high-temperature semiconductor device can be exposed to continuous temperature of 150° C. or higher.

High-temperature barrier region 204 can also serve as a nucleation layer for III-V growth on the underlying substrate 202.

As shown in FIG. 2B, a buffer layer 206 overlies high-temperature barrier region 204. A buffer layer 206 can be (In)GaAs. A buffer layer 206 can be lattice matched or pseudomorphically strained with respect to the substrate 202.

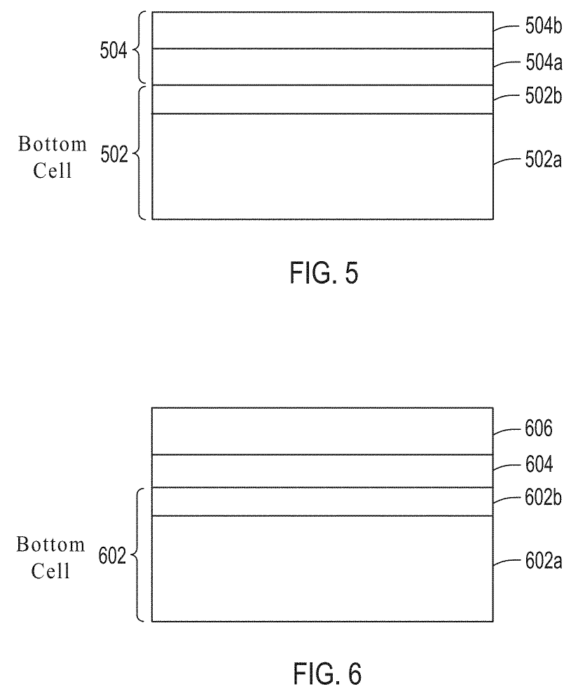

FIGS. 3-6 show an example of a process flow for growing the semiconductor structures shown in FIG. 2, wherein the substrate is Ge. First (FIG. 3), a p-doped germanium substrate (302) is provided and cleaned to remove native oxides prior to any atomic-layer deposition. The substrate may be cleaned in a gaseous environment such as an AsH₃ environment or a PH₃ environment. This step also allows the group V atoms to diffuse into the upper region of germanium (FIG. 3). An emitter region is formed as the upper germanium region is doped with a group V element comprising arsenic or phosphorus, transforming the germanium substrate (402) into an active n-p junction (FIG. 4), with a p-doped region 402a and an n-doped region 402b. The extent of group-V diffusion can be influenced by thermal exposure during substrate cleaning, epitaxial growth, and post-growth annealing treatments. In some embodiments, a phosphide layer or an arsenide layer can be deposited on the top surface of substrate 402, with the deposition conditions allowing diffusion of the group V atoms into substrate 402 to form the n-doped region. A high-temperature barrier region 504 can be epitaxially grown over the p-doped germanium junction 502 (FIG. 5). A high-temperature barrier region 504 can comprise an indium-free barrier layer, comprising AlP, GaP or AlGaP layer (layer 504a) and can have a thickness equal to or less than about 1.3 nm or less than or equal to five monolayers. High-temperature barrier region 504 can comprise an optional overlying barrier layer (504b) that can have a thickness, for example, within a range 0.5 nm to 200 nm, from 2 nm to 150 nm, from 5 nm to 100 nm, from 5 nm to 50 nm, or from 10 nm to 40 nm. A high-temperature barrier layer can comprise an indium-free barrier layer comprising AlPSb, GaPSb or AlGaPSb, or can comprise an aluminum-containing barrier layer comprising InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi. A high-temperature barrier region 504 can have a thickness, for example, less than 200 nm, less than 100 nm, less than 50 nm, less than 20 nm, less than 10 nm or less than 1 nm. A high-temperature barrier region 504 can be, for example, from 2 nm to 20 nm thick, from 2 nm to 10 nm, or from 2 nm to 5 nm. A high-temperature barrier region 504 can be, for example, from 4 nm to 10 nm thick.

A buffer layer 606 (FIG. 6) can then be epitaxially grown over high-temperature barrier region 604, overlying germanium substrate 602 including a p-doped region 602a and an n-doped region 602b. A buffer layer can comprise (In)GaAs. A (In)GaAs buffer layer can be, for example, from 100 nm to 900 nm thick, from 200 nm to 800 nm thick, from 300 nm to 700 nm thick, or from 400 nm to 600 nm thick.

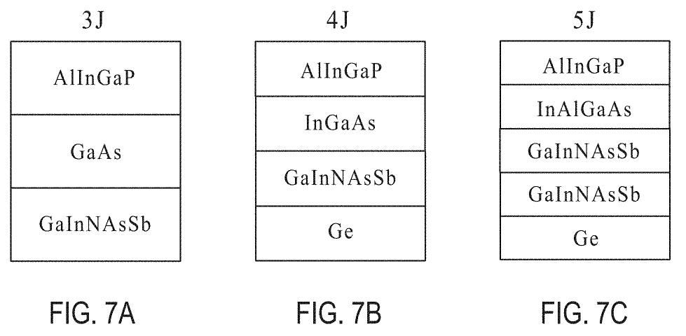

A high-temperature barrier region with an active germanium junction (FIG. 2) can be incorporated into a dilute nitride-containing multijunction photovoltaic cell (see for example FIGS. 7A-7C). FIGS. 7A-7C show examples of three-junction (3J), four junction (4J), and five junction (5J) multijunction solar cells, respectively.

Examples of dilute nitrides include GaInNAsSb, GaInNAsBi, GaInNAsSbBi, GaNAsSb, GaNAsBi and GaNAsSbBi. The lattice constant and band gap of a dilute nitride can be controlled by the relative fractions of the different group IIIA and group VA elements. Further, high quality material may be obtained by optimizing the composition around a specific lattice constant and band gap, while limiting the total antimony and/or bismuth content, for example, to no more than 20 percent of the group V lattice sites. Antimony and bismuth are believed to act as surfactants that promote smooth growth morphology of the III-AsNV dilute nitride alloys. Thus, by tailoring the compositions (i.e., the elements and quantities) of a dilute nitride material, a wide range of lattice constants and band gaps may be obtained. The band gaps and compositions can be tailored so that the short-circuit current density produced by the dilute nitride junction will be the same as or slightly greater than the short-circuit current density of each of the other junctions in the solar cell.

Dilute nitrides require a post-growth thermal treatment to improve material quality. Thermal treatment increases the solubility of nitrogen in the material, which would otherwise form clusters and structural defects.

A high-temperature barrier region can be situated between an underlying germanium junction and an overlying dilute nitride junction.

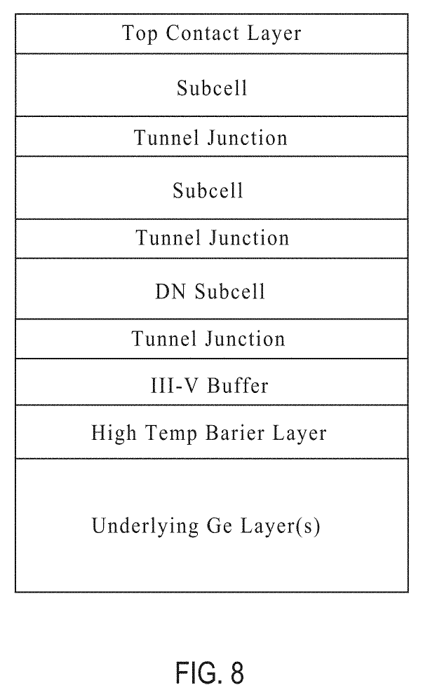

FIG. 8 shows functionally, the layers of a four-junction (4J) multijunction solar cell. Taking Ge as an exemplary substrate, the Ge layer(s) can form a bottom subcell, having a p-n junction. The high-temperature barrier region is then deposited onto the substrate, followed by a buffer layer. A tunnel junction is then formed, followed by the dilute nitride subcell. In this example, two additional subcells are included in the structure, with all subcells coupled by tunnel junctions, providing series connection of the multiple p-n junctions (subcells).

A practitioner skilled in the art understands that other types of layers may be incorporated or omitted in a photovoltaic cell to create a functional device and are not necessarily described here in detail. These other types of layers include, for example, coverglass, anti-reflection coating (ARC), contact layers, front surface field (FSF), tunnel junctions, window, emitter, back surface field (BSF), nucleation layers, buffer layers, and a substrate or wafer handle. In each of the embodiments described and illustrated herein, additional semiconductor layers can be present to create a photovoltaic cell device. Specifically, cap or contact layer(s), ARC layers and electrical contacts (also denoted as the metal grid) can be formed above the top subcell, and buffer layer(s), the substrate or handle, and bottom contacts can be formed or be present below the bottom subcell. A substrate can also function as the bottom junction, such as in a germanium junction. Multijunction photovoltaic cells may also be formed without one or more of the layers listed above, as known to those skilled in the art. Each of these layers requires careful design to ensure that the multijunction photovoltaic cell achieves high performance.

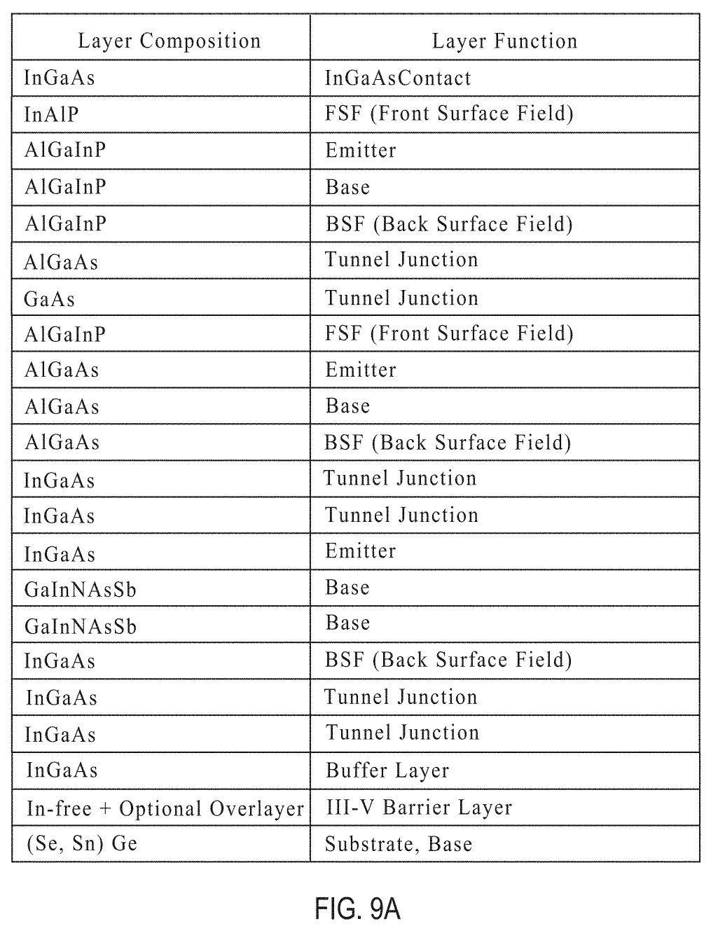

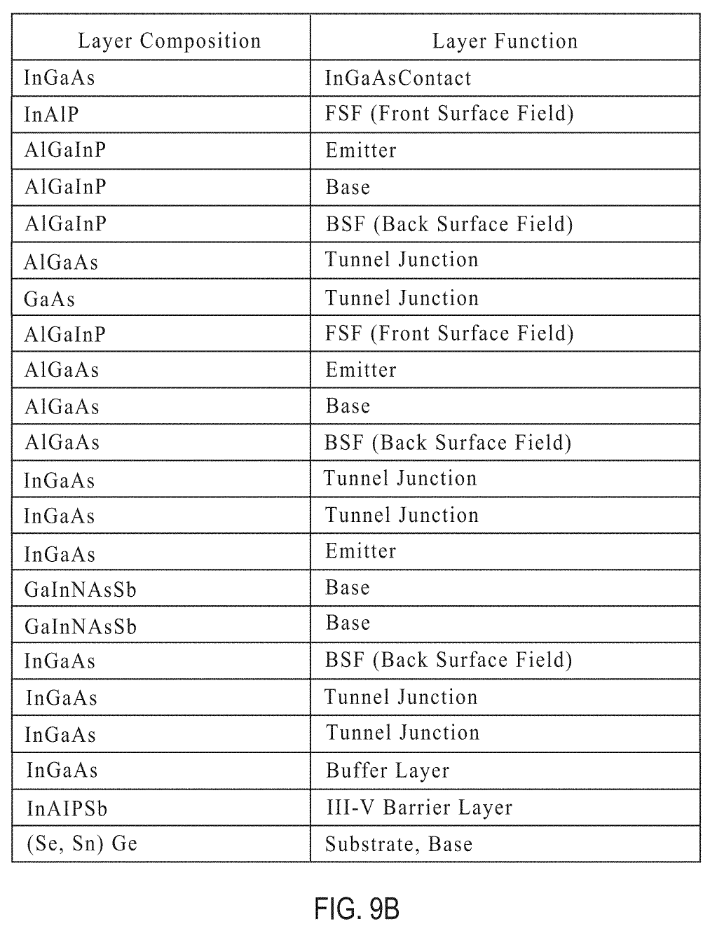

FIG. 9A shows an example of a 4J structure (e.g., AlInGaP/(Al,In)GaAs/GaInNAsSb/Ge) with a high-temperature barrier region comprising an indium-free barrier layer with an optional overlayer, and illustrating possible additional semiconductor layers that may be present in a multijunction photovoltaic cell.

FIG. 9B shows an example of a 4J structure (e.g., AlInGaP/(Al,In)GaAs/GaInNAsSb/Ge) with a high-temperature barrier region comprising a InAlPSb layer, and illustrating possible additional semiconductor layers that may be present in a multijunction photovoltaic cell.

The high-temperature barrier region not only protects the underlying group-IV substrate from group V diffusion, but it also can provide a surface with a good surface morphology that enables high quality growth of the subsequent layers, and high-quality interfaces between the layers of differing composition. Thus, the high-temperature barrier region can also serve as a nucleation layer.

The attenuation of arsenic diffusion due to the high-temperature barrier region correlates with high quality device performance. Various metrics can be used to characterize the quality of an optoelectronic device, including, for example, the Eg/q-Voc, the efficiency over a range of irradiance energies, the open circuit voltage, Voc, and the short circuit current density, Jsc. Those skilled in the art can understand how to extrapolate the Voc and Jsc measured for a junction having a particular dilute nitride base thickness to other junction thicknesses. The Jsc and the Voc are the maximum current density and voltage, respectively, for a photovoltaic cell. However, at both of these operating points, the power from the photovoltaic cell is zero. The fill factor (FF) is a parameter which, in conjunction with Jsc and Voc, determines the maximum power from a photovoltaic cell. The FF is defined as the ratio of the maximum power produced by the photovoltaic cell to the product of Voc and Jsc. Graphically, the FF is a measure of the “squareness” of the photovoltaic cell and is also the area of the largest rectangle that will fit within the IV (current-voltage) curve.

Seemingly small improvements in the efficiency of a junction/subcell can result in significant improvements in the efficiency of a multijunction photovoltaic cell. Again, seemingly small improvements in the overall efficiency of a multijunction photovoltaic cell can result in dramatic improvements in output power, reduce the area of a photovoltaic array, and reduce costs associated with installation, system integration, and deployment.

Photovoltaic cell efficiency is important as it directly affects the photovoltaic module power output. For example, assuming a 1 m² photovoltaic panel having an overall 24% conversion efficiency, if the efficiency of multijunction photovoltaic cells used in a module is increased by 1% such as from 40% to 41% under 500 suns, the module output power will increase by about 2.7 KW.

Generally, a photovoltaic cell contributes around 20% to the total cost of a photovoltaic power module. Higher photovoltaic cell efficiency means more cost-effective modules. Fewer photovoltaic devices are then needed to generate the same amount of output power, and higher output power with fewer devices leads to reduced system costs, such as costs for mounting racks, hardware, wiring for electrical connections, etc. In addition, by using high efficiency photovoltaic cells to generate the same power, less land area, fewer support structures, and lower labor costs are required for installation.

Photovoltaic modules are a significant component in spacecraft power systems. Lighter weight and smaller photovoltaic modules are always preferred because the lifting cost to launch satellites into orbit is super expensive. Photovoltaic cell efficiency is especially important for space power applications to reduce the mass and fuel penalty due to large photovoltaic arrays. The higher specific power (watts generated over photovoltaic array mass), which determines how much power one array will generate for a given launch mass, can be achieved with more efficient photovoltaic cells because the size and weight of the photovoltaic array will be less for the same power output.

As an example, compared to a nominal photovoltaic cell having a 30% conversion efficiency, a 1.5% increase in multijunction photovoltaic cell efficiency can result in a 4.5% increase in output power, and a 3.5% increase in multijunction photovoltaic cell efficiency can result in an 11.5% increase in output power. For a satellite having a 60 kW power requirement, the use of higher efficiency subcells can result in photovoltaic cell module cost savings from $0.5 million to $1.5 million, and a reduction in photovoltaic array surface area of 6.4 m² to 15.6 m², for multijunction photovoltaic cells having increased efficiencies of 1.5% and 3.5%, respectively. The overall cost savings will be even greater when costs associated with system integration and launch are taken into consideration.

Semiconductor structures as shown schematically in FIGS. 2A and 2B, with an InGaAs buffer layer, and a high-temperature barrier region were grown on Ge substrates and evaluated for the ability of the high-temperature barrier region to provide a smooth surface morphology, and to preserve junction performance with a thermal treatment used to condition dilute nitrides. High-temperature barrier regions were formed using an AlP layer as the indium-free barrier layer and an InAlP overlayer. High-temperature barrier regions were also formed using InAlP. The AlP layers were about 0.5 nm (or two monolayers) thick, with InAlP layer thicknesses between 2 nm and 20 nm. For comparison purposes, structures incorporating an InGaP layer as the nucleation and barrier layer, replacing the high-temperature barrier region were also grown, with thicknesses up to 20 nm.

In all cases, the InGaAs layer was 200 nm thick. Devices were formed according to the process steps summarized in FIGS. 3-6, with the diffused Ge junction formed using AsH₃.

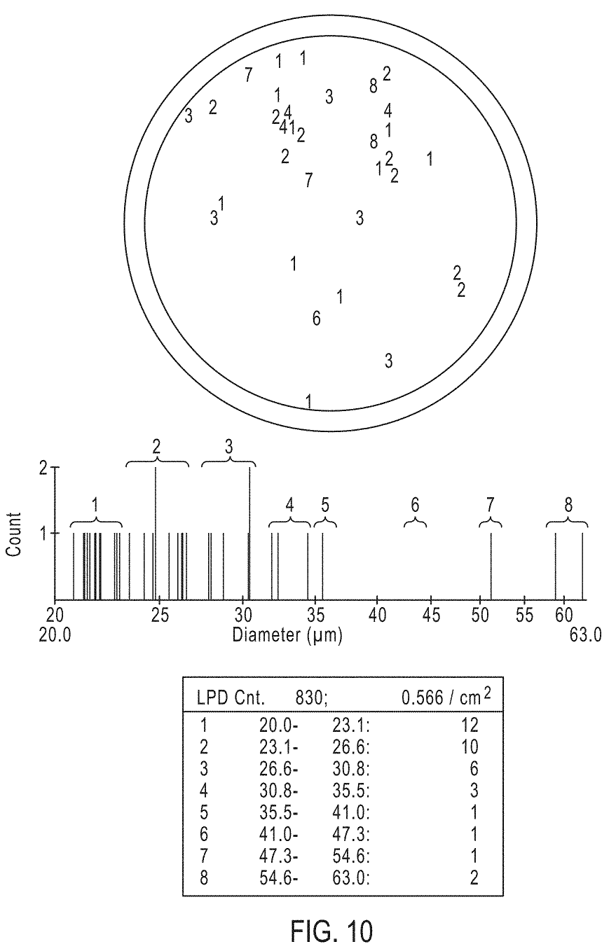

The surface morphology of structures incorporating a high-temperature barrier region was measured using Surfscan® wafer inspection (KLA Tencor). FIG. 10 shows a surface scan image for a wafer having an AlP/InAlP barrier region, and the metrology data is summarized in Table 2. For the sample having a AlP/InAlP barrier region, the haze is low, indicating good epitaxial morphology.

TABLE 2
Surfscan ® results for a AlP/InAlP buffer region.

| | Wafer | All | Haze | Haze | LPD/ |
|---|---|---|---|---|---|
| Design | ID | Defects | Avg | Peak | cm² |
| AlP/InAlP | 5 | 73 | 0.0327 | 140 | 0.912 |
| | 6 | 61 | 0.00524 | 48 | 0.927 |
| | 7 | 38 | 0.0438 | 331 | 0.566 |
| | 8 | 41 | 0.0479 | 137 | 0.597 |

The Ge cells were tested using an Abet Technologies Sun 2000 solar simulator single lamp source with a long-pass filter to simulate the light absorption of the top three junctions in a 4J solar cell. The sun simulator was calibrated using a reference sample. The reference sample current was calibrated using a customize Newport quantum efficiency (QE) system based on a NIST calibration traceable detector and the AMO reference spectrum.

The structures comprise a Ge sub-cell, with a high-temperature barrier region and an overlying buffer layer. The Ge cells were tested with and without thermal treatment, and the performance was assessed by measuring the Jsc (short circuit current density), Voc (open circuit voltage), fill factor, and efficiency. The thermal annealing conditions were suitable for thermally annealing dilute nitride subcells to achieve high performance. The devices were subjected to thermally annealing at a temperature within a range from 600° C. to 900° C. for a duration from 5 seconds to 3 hours.

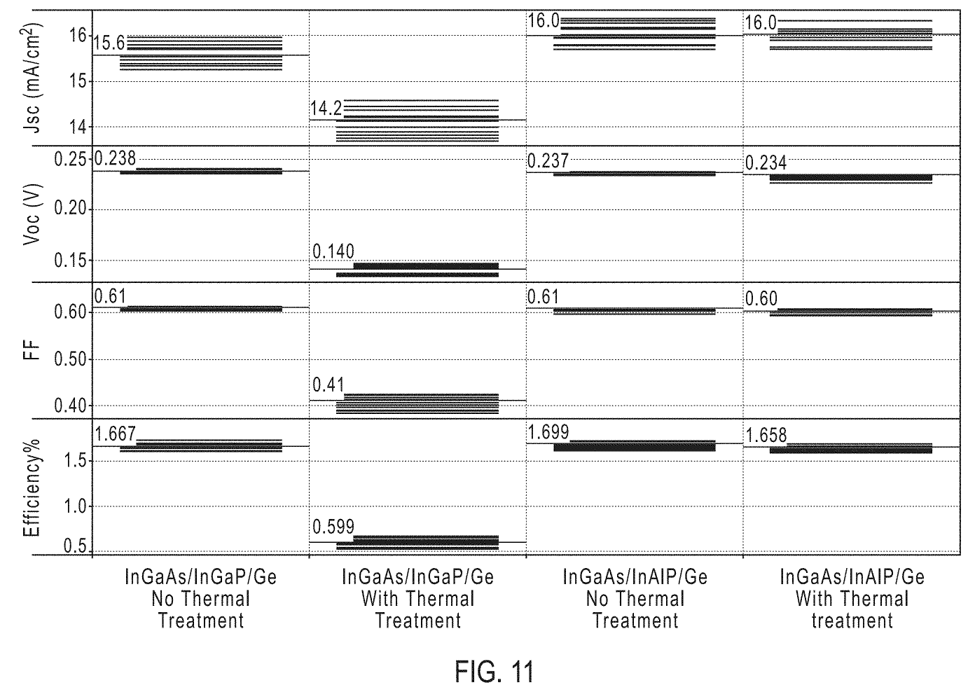

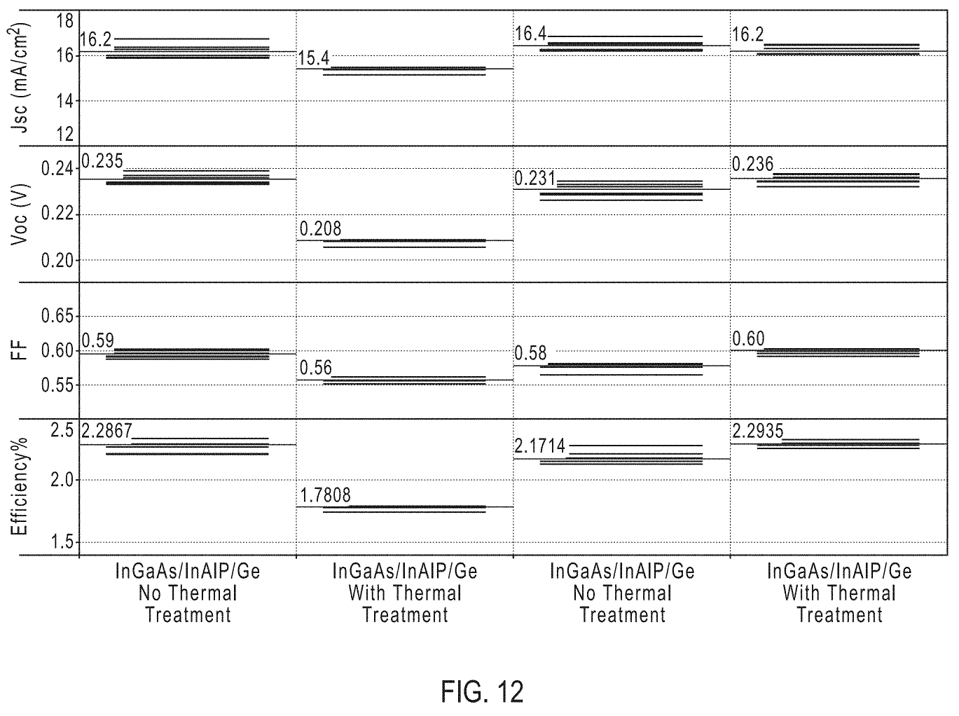

FIG. 11 shows the performance of a Ge junction of a InGaAs/InGaP/Ge structure and of a InGaAs/InAlP/Ge structure before and after thermal annealing. The thermal annealing conditions were suitable for thermally annealing dilute nitride subcells to achieve high performance. The devices were subjected to thermal annealing at a temperature within a range from 600° C. to 900° C. for a duration from 5 seconds to 5 hours.

The results demonstrate that a high-temperature barrier region having an InAlP layer was effective in preserving the Jsc, Voc, fill factor of the high efficiency photovoltaic cell. In other words, with the InAlP barrier layer, the properties of the germanium junction were not degraded by the thermal annealing conditions. That is, the barrier layer is configured to withstand the effects of annealing on device performance. The values reported represent calculated median values of twelve (12) replicates of 2×2 cm² devices in 4-inch wafers. While thermal treatment caused all performance values for the Ge junction of an InGaAs/InGaP/Ge structure to decrease, the values for the Ge junction of an InGaAs/InAlP/Ge structure were maintained following thermal treatment. Because the active germanium junction of the InGaAs/InAlP/Ge structure performs with design-targeted electrical properties despite the aggressive thermal treatment, it can be implied that the InAlP barrier layer prevented or minimized arsenic diffusion from the InGaAs buffer layer into the germanium junction.

Presumably, a thicker high-temperature barrier region would be better at attenuating arsenic diffusion from InGaAs into germanium, making the germanium junction less sensitive to thermal load. Excessive thickness of the high-temperature barrier region, however, can also result in residual strain that can propagate structural defects or increase haze in the final device structure, in addition to increasing production cost.

FIG. 12 shows the performance of a Ge junction of InGaAs/InAlP/Ge structures with two different InAlP thicknesses: 1× and 1.14×. The performance of both Ge junctions was measured with and without a thermal annealing. Germanium junction performance was better using a thicker high-temperature barrier region, i.e., 1.14×InAlP. Both thicknesses were within the range of 5 nm to 50 nm.

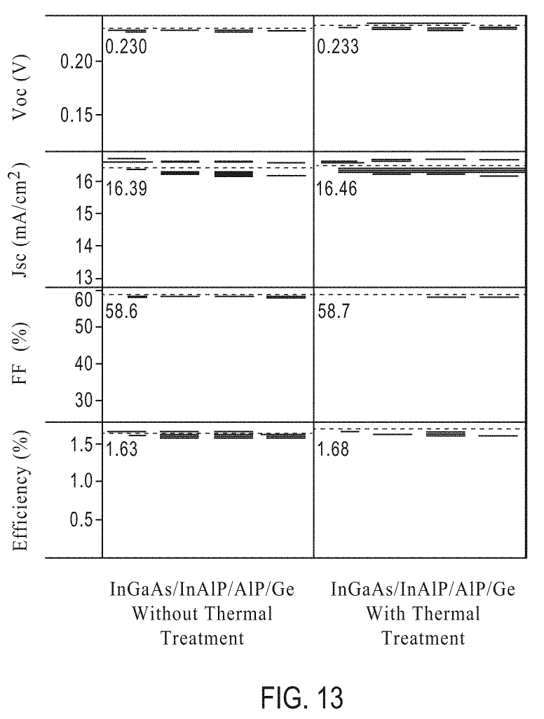

FIG. 13 shows the performance of a InGaAs/InAlP/AlP/Ge junction before and after thermal annealing. For the structures with the AlP/InAlP barrier, the performance parameters Jsc, Voc, fill factor and efficiency are preserved, showing that the properties of the germanium junction are not degraded by the thermal annealing conditions. In comparison, a structure using only a thin comparable thickness of InAlP layer suffered some degradation of the germanium junction parameters during the thermal annealing process. Thus, the inclusion of an indium-free barrier layer, such as an AlP layer can reduce the thickness of the InAlP required to form a high-temperature barrier region.

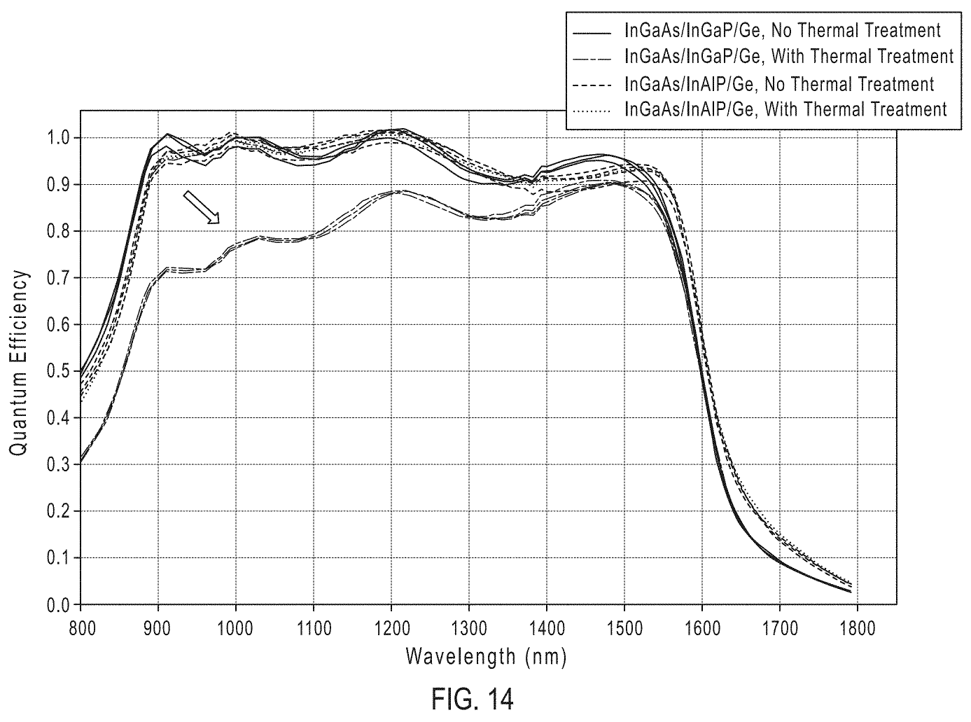

FIG. 14 shows the efficiency of germanium junctions of InGaAs/InGaP/Ge and InGaAs/InAlP/Ge structures over a range of irradiance energies, from 800 nm (1.55 eV) to 1,800 nm (0.69 eV). The wavelength-dependent efficiency of devices incorporating an InAlP high-temperature barrier region was maintained following thermal treatment. The wavelength-dependent efficiency of devices having an InGaP layer decreased following exposure to the same thermal treatment.

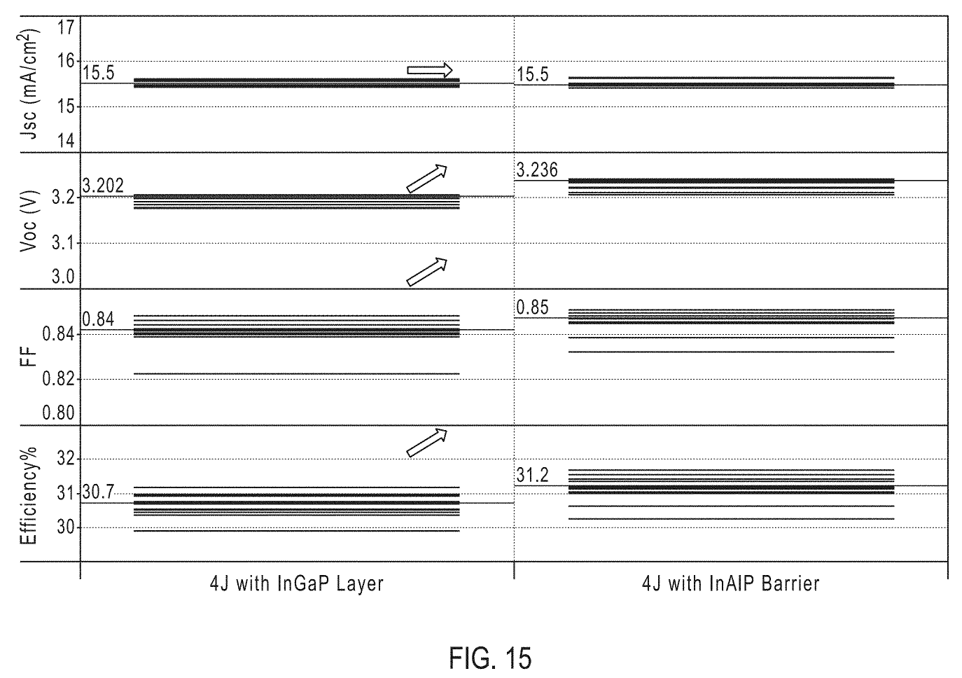

FIG. 15 shows the performance of the InGaAs/InGaP/Ge and InGaAs/InAlP/AlP/Ge junctions of FIG. 14 after thermal annealing.

Using only an InAlP barrier layer, a thicker barrier layer is better at attenuating arsenic diffusion from InGaAs into germanium, making the germanium junction less sensitive to thermal load. Excessive thickness of the high-temperature barrier region, however, can also result in residual strain that can propagate structural defects or increase haze in the final device structure, in addition to increasing production cost.

Using an AlP/InAlP barrier, the inclusion of AlP provides a high-temperature barrier region that is better at attenuating arsenic diffusion from InGaAs into germanium, making the germanium junction less sensitive to thermal load. The use of a thin AlP layer in the barrier reduces the thickness of the overlying InAlP barrier layer, and results in comparable performance to thicker InAlP layers. Because the active InGaAs/InAlP/AlP/Ge germanium junction performs with design-targeted electrical properties despite the aggressive thermal treatment, it can be implied that the inclusion of AlP in the barrier layer prevented or minimized arsenic diffusion from the (In)GaAs buffer layer into the germanium junction.

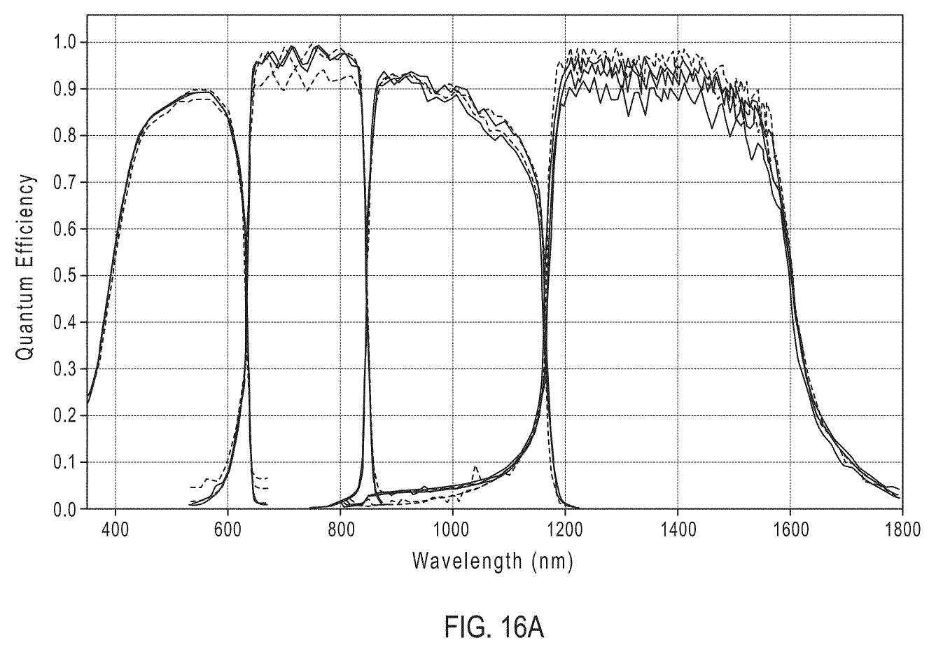

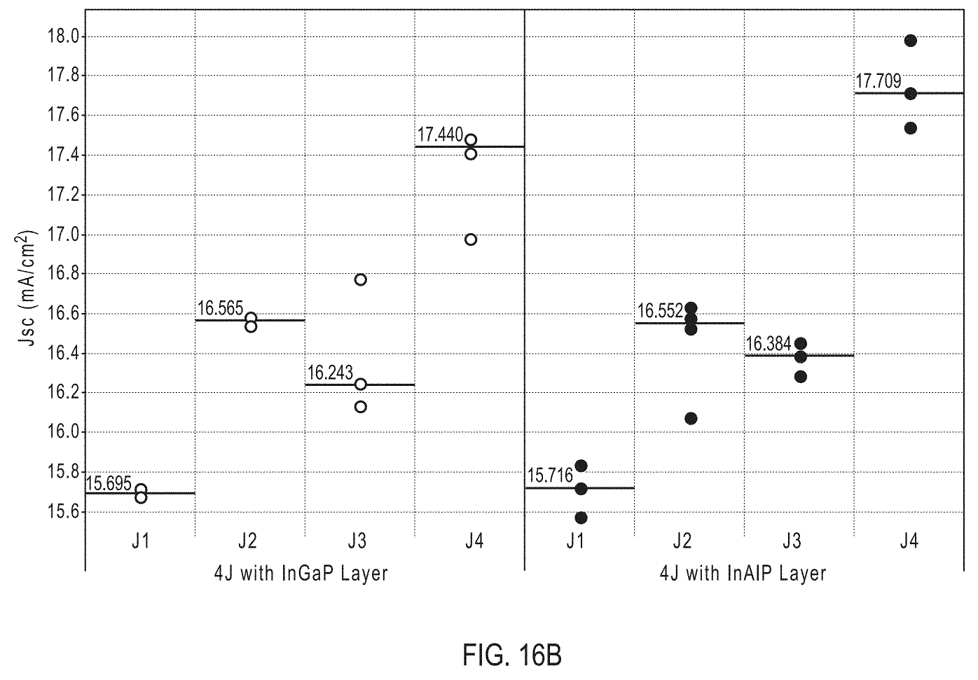

FIG. 16A shows the efficiency as a function of irradiation wavelength for each of the junctions of 4J multijunction photovoltaic cell with a high-temperature barrier region and following high-temperature annealing. The 4J multijunction photovoltaic cell had the structure shown in FIG. 7B with a InGaAs/InAlP/AlP structure between the GaInNAsSb junction and the active Ge junction.

FIG. 16B shows the short circuit current density Jsc for each of the junctions of the 4J multijunction photovoltaic cell of FIG. 16A.

It is believed that the strong Al—P bonding in the high-temperature barrier region prevents diffusion of phosphorus into the n-p germanium junction and that the aluminum acts as a getter to prohibit arsenic diffusion.

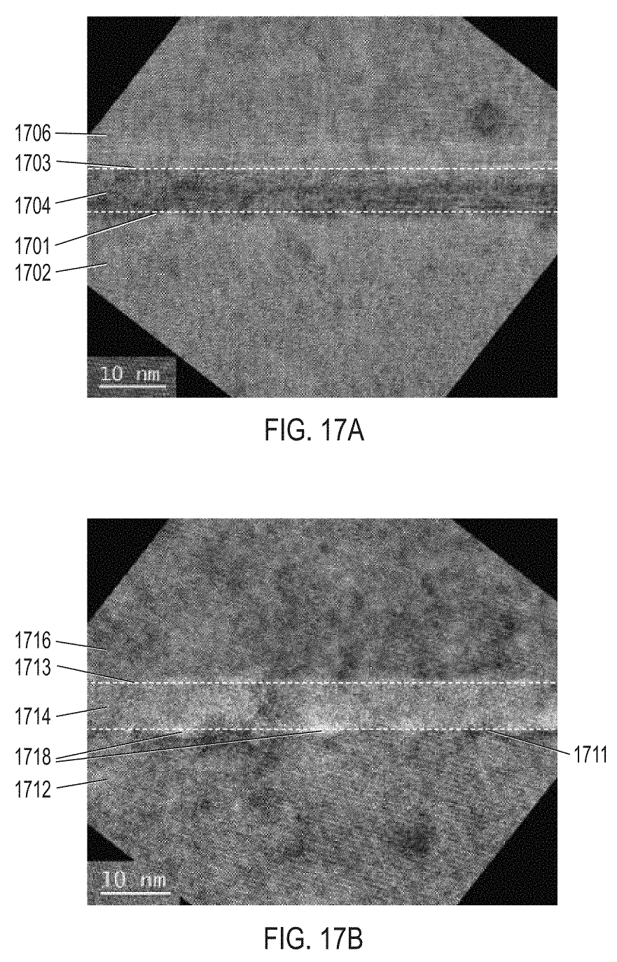

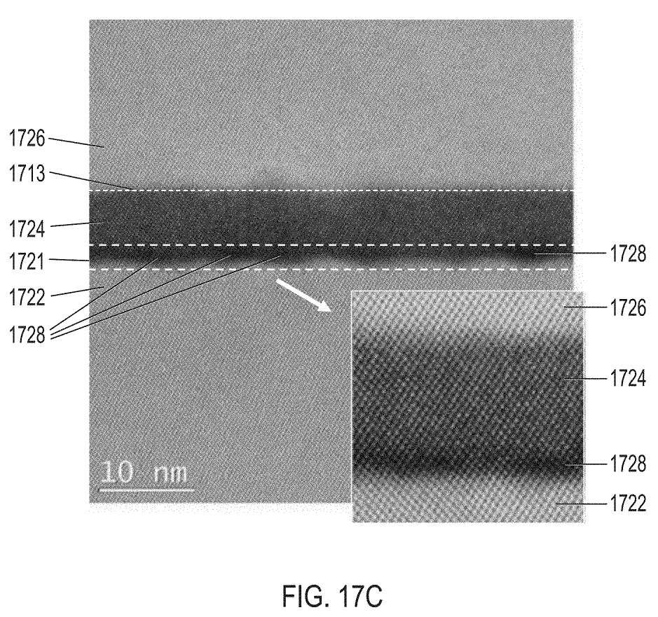

FIG. 17A shows a transmission electron microscopy (TEM) image of a high-temperature barrier region consisting of a single InAlP high-temperature barrier layer, according to the example shown in FIG. 2A. FIG. 17A shows a Ge substrate 1702, a high-temperature barrier region 1704 formed on substrate 1702, with an interface 1701, and a buffer layer 1706 formed on high-temperature barrier region 1704, with an interface 1703. High-temperature barrier region 1704 is an InAlP layer and buffer layer 1706 is InGaAs. The Ge substrate exhibits some surface roughness. The interface 1701 between the substrate and the high-temperature barrier region is therefore not perfectly smooth and can be corrugated. However, the interface between high-temperature barrier region 1704 and buffer layer 1706 is smoother, with the high-temperature barrier region helping to planarize or flatten the epitaxial surface for subsequent III-V materials to be formed on.

FIG. 17B shows a transmission electron microscopy (TEM) image of a high-temperature barrier layer, according to the example shown in FIG. 2B. FIG. 17B shows a Ge substrate 1712, a high-temperature barrier region 1714 formed on substrate 1712, with an interface 1711, and a buffer layer 1716 formed on high-temperature barrier region 1714, with an interface 1713. High-temperature barrier region 1714 is an indium-free AlP layer followed by an InAlP layer and buffer layer 1716 is InGaAs. The Ge substrate exhibits some surface roughness. The interface 1711 between the substrate and the barrier layer is therefore not perfectly smooth and can be corrugated. Higher brightness regions 1718 at the interface indicate higher aluminum content at those regions. In this example, the AlP layer does not provide complete layer coverage. Surface roughness is typical in any Ge substrate, and the AlP can fill “troughs” or “pits” at the rough surface, indicated by regions 1718, to provide a flatter surface for subsequent layer formation. The interface 1713 between high-temperature barrier region 1714 and buffer layer 1716 is smoother, with the high-temperature barrier region helping to planarize or flatten the epitaxial surface for subsequent III-V materials to be formed on.

To investigate the interface between the Ge substrate and the high-temperature barrier region, high-angle annular dark-field scanning transmission electron microscopy (HAADF-STEM) imaging has been performed. In this technique, an annular dark-field (ADF) detector receives inelastically scattered electrons or thermal diffuse scattering (TDS) at high angles. FIG. 17C shows a HAADF-STEM image for a two-layer barrier, similar to that shown in FIG. 17B. FIG. 17C shows a Ge substrate 1722, a high-temperature barrier region 1724 formed on substrate 1722, with an interface 1721, and a buffer layer 1726 formed on barrier region 1724, with an interface 1723. High-temperature barrier region 1724 consists of an indium-free AlP layer and an InAlP layer; and overlying buffer layer 1726 is InGaAs. The Ge substrate exhibits some surface roughness, which results in a corrugated surface interface 1721, with a roughness of about +/−0.5 nm, indicated within the white dashed lines. For this image, the darker regions 1728 at the interface indicate higher aluminum content at those regions. It is apparent that the AlP layer fills in the corrugated structure, and that the interface 1721, while not perfectly smooth, has a higher Al concentration at the interface region 1721 than exists in the overlying InAlP layer of barrier region 1724. The AlP high-temperature barrier layer may not be perfectly smooth and may not provide complete coverage of the substrate surface. However, as can be seen by region 1728, it can be identified as either a continuous layer, or a region that may not be continuous, at the interface 1721 within the two-layer high-temperature barrier region. The interface 1723 between high-temperature barrier region 1724 and buffer layer 1726 is smoother, showing that the high-temperature barrier region 1724 helps to planarize or flatten the epitaxial surface for subsequent III-V materials to be formed on.

Methods of fabricating a semiconductor device such as a dilute nitride-containing multijunction solar cell provided by the present disclosure can comprise providing a p-type semiconductor; forming a n-type region in the p-type semiconductor by exposing the p-type semiconductor to a gas phase n-type dopant to form a n-p junction; depositing a high-temperature barrier region over the n-type region; depositing an group-V-containing layer over the high-temperature barrier region; and thermally annealing the semiconductor device at a temperature within a range from 600° C. to 900° C. for a duration from 5 seconds to 5 hours. Following the thermal annealing step, the semiconductor device retains the performance attributes as before the thermal treatment.

A plurality of layers can be deposited on a substrate in a first materials deposition chamber. The plurality of layers may include etch stop layers, release layers (i.e., layers designed to release the semiconductor layers from the substrate when a specific process sequence, such as chemical etching, is applied), contact layers such as lateral conduction layers, buffer layers, or other semiconductor layers. In one specific embodiment, the sequence of layers deposited is buffer layer(s), then release layer(s), and then lateral conduction or contact layer(s). Next, the substrate is transferred to a second materials deposition chamber where one or more junctions are deposited on top of the existing semiconductor layers. The substrate may then be transferred to either the first materials deposition chamber or to a third materials deposition chamber for deposition of one or more junctions and then deposition of one or more contact layers. Tunnel junctions are also formed between the junctions.

The movement of the substrate and semiconductor layers from one materials deposition chamber to another is defined as the transfer. For example, a substrate is placed in a first materials deposition chamber, and then the buffer layer(s) and the bottom junction(s) are deposited. Then the substrate and semiconductor layers are transferred to a second materials deposition chamber where the remaining junctions are deposited. The transfer may occur in vacuum, at atmospheric pressure in air or another gaseous environment, or in any environment in between. The transfer may further be between materials deposition chambers in one location, which may or may not be interconnected in some way or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

Dilute nitride junctions can be deposited in a first materials deposition chamber, and the (Al,In)GaP and (Al,In)GaAs junctions can be deposited in a second materials deposition chamber, with tunnel junctions formed between the junctions. A transfer can occur in the middle of the growth of one junction, such that a junction has one or more layers deposited in one materials deposition chamber and one or more layers deposited in a second materials deposition chamber.

Some or all of the layers of a dilute nitride junction and the tunnel junctions can be deposited in one materials deposition chamber by molecular beam epitaxy (MBE), and the remaining layers of the photovoltaic cell are deposited by chemical vapor deposition (CVD) in another materials deposition chamber. For example, a substrate is placed in a first materials deposition chamber and layers that may include nucleation layers, buffer layers, emitter and window layers, contact layers and a tunnel junction are grown on the substrate, followed by one or more dilute nitride junctions. If there is more than one dilute nitride junction, then a tunnel junction is grown between adjacent junctions. One or more tunnel junction layers may be grown, and then the substrate is transferred to a second materials deposition chamber where the remaining photovoltaic cell layers are grown by chemical vapor deposition. In certain embodiments, the chemical vapor deposition system is a MOCVD system. In a related embodiment of the invention, a substrate is placed in a first materials deposition chamber and layers that may include nucleation layers, buffer layers, emitter and window layers, contact layers and a tunnel junction are grown on the substrate by chemical vapor deposition. Subsequently, the top junctions, two or more, are grown on the existing semiconductor layers, with tunnel junctions grown between the junctions. Part of the topmost dilute nitride junction, such as the window layer, may then be grown. The substrate is then transferred to a second materials deposition chamber where the remaining semiconductor layers of the topmost dilute nitride junction may be deposited, followed by up to three more dilute nitride junctions, with tunnel junctions between them.

In some embodiments, a surfactant, such as Sb or Bi, may be used when depositing any of the layers of the device. A small fraction of the surfactant may also incorporate within a layer.

A photovoltaic cell can be subjected to one or more thermal annealing treatments after growth. For example, a thermal annealing treatment includes the application of a temperature of 400° C. to 1000° C. for between 10 microseconds and 10 hours. Thermal annealing may be performed in an atmosphere that includes air, nitrogen, arsenic, arsine, phosphorus, phosphine, hydrogen, forming gas, oxygen, helium and any combination of the preceding materials. In certain embodiments, a stack of junctions and associated tunnel junctions may be annealed prior to fabrication of additional junctions.

Although the focus of this disclosure has been on the use of high-temperature barrier regions comprising AlP or InAlP in dilute-nitride-containing multijunction photovoltaic cells, a high-temperature barrier region can comprise indium-free materials, including, for example, GaP, AlGaP, AlPSb, and GaPSb. A high-temperature barrier region can comprise an aluminum-containing barrier layer, comprising, for example, InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi.

High-temperature barrier regions provided by the present disclosure can be used in any semiconductor device to prevent, minimize, control, or modify the diffusion of a group V element such as arsenic into an underlying semiconductor layer during exposure to high temperature. The high-temperature exposure can result from processing of the semiconductor structure and/or the semiconductor device. For example, the high-temperature exposure can result from the high-temperature annealing of a dilute nitride material such as, for example, thermal annealing at a temperature within a range from 600° C. to 900° C. for a duration from 5 seconds to 3 hours. High-temperature exposure can occur during use such as in power devices or in semiconductor devices used in space systems. A semiconductor device can comprise one or more high-temperature barrier regions provided by the present disclosure.

High-temperature barrier regions provided by the present disclosure can be incorporated into semiconductor devices such as power converters, transistors, lasers, light emitting diodes, optoelectronic devices, and solar cells such as a multijunction photovoltaic cells.

Semiconductor devices such as multijunction photovoltaic cells incorporating a high-temperature barrier region can be incorporated into a module or sub-assembly. A module or sub-assembly can be incorporated into an electronic system. In the case of a photovoltaic module, a power system can comprise one or more photovoltaic modules.

### ASPECTS OF THE INVENTION

Aspect 1. A semiconductor structure comprising: a first semiconductor layer, wherein the first semiconductor layer comprises a group V element; a high-temperature barrier region underlying the first semiconductor layer, wherein the high-temperature barrier region comprises one or more barrier layers, wherein at least one of the barrier layers comprises an indium-free barrier layer or an aluminum-containing barrier layer; and a second semiconductor layer underlying the high-temperature barrier region.

Aspect 2. The semiconductor structure of aspect 1, wherein the group V element comprises arsenic.

Aspect 3. The semiconductor structure of any one of aspects 1 to 2, wherein the first semiconductor layer comprises (In)AlGaAs.

Aspect 4. The semiconductor structure of any one of aspects 1 to 2, wherein the first semiconductor layer comprises (In)GaAs.

Aspect 5. The semiconductor structure of any one of aspects 1 to 4, wherein the high-temperature barrier region comprises one barrier layer.

Aspect 6. The semiconductor structure of any one of aspects 1 to 4, wherein the high-temperature barrier region comprises two barrier layers.

Aspect 7. The semiconductor structure of any one of aspects 1 to 6, wherein the high-temperature barrier region has a thickness from 0.25 nm to 200 nm.

Aspect 8. The semiconductor structure of any one of aspects 1 to 7, wherein each of the one or more barrier layers independently has a thickness from 0.25 nm to 200 nm.

Aspect 9. The semiconductor structure of any one of aspects 1 to 8, wherein the high-temperature barrier region comprises an indium-free barrier layer.

Aspect 10. The semiconductor structure of aspect 9, wherein the indium-free barrier layer comprises AlP, GaP, AlGaP, AlPSb, GaPSb, or AlGaPSb.

Aspect 11. The semiconductor structure of aspect 10, further comprising a second barrier layer overlying the indium-free barrier layer, wherein the second barrier layer comprises InAlP, InGaP, AlGaP, AlP, GaP, InAlPSb, InAlPBi, InAlPSbBi, AlInGaP, AlInGaPSb, AlInGaPBi, AlInGaPSbBi, AlPSb, GaPSb, AlGaPSb, AlPBi, AlPSbBi, AlAsSb, AlAsBi, AlAsSbBi, AlN, AlNSb, AlNBi, or AlNSbBi.

Aspect 12. The semiconductor structure of any one of aspects 1 to 11, wherein the high-temperature barrier region comprises an aluminum-containing barrier layer.

Aspect 13. The semiconductor structure of aspect 12, wherein the aluminum-containing barrier layer comprises InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi.

Aspect 14. The semiconductor structure of aspect 12, wherein the aluminum-containing barrier layer comprises InAlP.

Aspect 15. The semiconductor structure of any one of aspects 1 to 14, wherein the high-temperature barrier region comprises an aluminum/phosphorous-containing barrier layer.

Aspect 16. The semiconductor structure of aspect 15, wherein the aluminum/phosphorous-containing barrier layer comprises InAlP, InAlPSb, InAlPBi, InAlPSbBi, AlInGaP, AlInGaPSb, AlInGaPBi, AlInGaPSbBi, AlP, AlPSb, AlPBi, or AlPSbBi.

Aspect 17. The semiconductor structure of any one of aspects 15 to 16, wherein the high-temperature barrier region comprises: first aluminum/phosphorous-containing barrier layer; and a second aluminum/phosphorous-containing barrier layer overlying the first aluminum/phosphorous-containing barrier layer.

Aspect 18. The semiconductor structure of aspect 17, wherein, each of the first aluminum/phosphorous-containing barrier layer and the second aluminum/phosphorous-containing barrier layer independently comprises InAlP, InAlPSb, InAlPBi, InAlPSbBi, AlInGaP, AlInGaPSb, AlInGaPBi, AlInGaPSbBi, AlP, AlPSb, AlPBi, or AlPSbBi.

Aspect 19. The semiconductor structure of aspect 17, wherein, the first aluminum/phosphorous-containing barrier layer comprises AlP; and the second aluminum/phosphorous-containing barrier layer comprises InAlP.

Aspect 20. The semiconductor structure of any one of aspects 1 to 19, wherein the second semiconductor layer comprises (Si,Sn)Ge.

Aspect 21. The semiconductor structure of any one of aspects 1 to 19, wherein the second semiconductor layer comprises Ge.

Aspect 22. The semiconductor structure of any one of aspects 1 to 21, wherein the second semiconductor layer comprises a n-p germanium junction.

Aspect 23. The semiconductor structure of aspect 22, wherein, the n-p germanium junction comprises an n-type region comprising an n-type dopant overlying a p-type region; and the n-type dopant comprises a group V atom.

Aspect 24. The semiconductor structure of aspect 23, wherein the n-type dopant consists essentially of arsenic.

Aspect 25. The semiconductor structure of any one of aspects 1 to 24, wherein, the first semiconductor layer comprises (In)GaAs; the high-temperature barrier region comprises an AlP layer and an InGaAlPSb layer overlying the AlP layer, wherein the InGaAlPSb layer comprises InGaAlP_{1-z}Sb_{z}, wherein 0≤z≤0.38; and the second semiconductor layer comprises an n-p (Si,Sn)Ge junction.

Aspect 26. The semiconductor structure of any one of aspects 1 to 24, wherein, the first semiconductor layer comprises an (In)GaAs; the high-temperature barrier region comprises a InAlPSb layer, wherein the InAlPSb layer comprises InAlP_{1-z}Sb_{z}, wherein 0≤z≤0.34; and the second semiconductor layer comprises an n-p (Si,Sn)Ge junction.

Aspect 27. The semiconductor structure of any one of aspects 1 to 26, wherein the first semiconductor layer is lattice matched to the second semiconductor layer.

Aspect 28. The semiconductor structure of any one of aspects 1 to 27, further comprising at least one third semiconductor layer overlying the first semiconductor layer.

Aspect 29. The semiconductor structure of aspect 28, wherein the at least one third semiconductor layer comprises a dilute nitride.

Aspect 30. The semiconductor structure of aspect 29, wherein the dilute nitride comprises GaInNAsSb, GaInNAsBi, GaInNAsSbBi, GaNAsSb, GaNAsBi, or GaNAsSbBi.

Aspect 31. The semiconductor structure of aspect 28, wherein the at least one third semiconductor layer comprises at least one dilute nitride junction.

Aspect 32. The semiconductor structure of aspect 31, wherein the at least one dilute nitride junction comprises GaInNAsSb, GaInNAsBi, GaInNAsSbBi, GaNAsSb, GaNAsBi, or GaNAsSbBi.

Aspect 33. The semiconductor structure of any one of aspects 28 to 32, wherein each of the semiconductor layers is lattice matched to each of the other semiconductor layers.

Aspect 34. A semiconductor device comprising the semiconductor structure of any one of aspects 1 to 33.

Aspect 35. A multijunction photovoltaic cell comprising the semiconductor structure of any one of aspects 1 to 33.

Aspect 36. A photovoltaic module comprising the multijunction photovoltaic cell of aspect 35.

Aspect 37. A power system comprising the photovoltaic module of aspect 36.

Aspect 38. A method of fabricating a semiconductor structure, comprising: depositing a high-temperature barrier region on a first semiconductor layer, wherein the high-temperature barrier region comprises one or more barrier layers, wherein at least one of the barrier layers comprises an indium-free barrier layer or an aluminum-containing barrier layer; and depositing a group V-containing layer on the high-temperature barrier region to form a semiconductor structure.

Aspect 39. The method of aspect 38, wherein the first semiconductor layer comprises a p-type semiconductor; and further comprising, depositing a high-temperature barrier region, forming an n-type region in the p-type semiconductor by exposing the p-type semiconductor to a gas phase n-type dopant to form a n-p junction, wherein depositing a high-temperature barrier region comprises depositing the high-temperature barrier region on the n-type region.

Aspect 40. The method of any one of aspects 38 to 39, wherein the n-type dopant comprises arsenic.

Aspect 41. The method of any one of aspects 38 to 40, wherein the first semiconductor layer comprises an n-p junction.

Aspect 42. The method of any one of aspects 38 to 41, comprising, after depositing the group V-containing layer, thermally annealing the semiconductor structure at a temperature within a range from 600° C. to 900° C. for a duration from 5 seconds to 8 hours.

Aspect 43. The method of any one of aspects 38 to 42, wherein the first semiconductor layer comprises (Si,Sn)Ge.

Aspect 44. The method of any one of aspects 38 to 43, wherein the indium-free barrier layer comprises AlP, GaP, AlGaP, AlPSb, GaPSb, or AlGaPSb.

Aspect 45. The method of any one of aspects 38 to 44, wherein the high temperature barrier region comprises: indium-free barrier layer; and a second barrier layer overlying the indium-free barrier layer, wherein the second barrier layer comprises InAlP, InGaP, AlGaP, AlP, GaP, InAlPSb, InAlPBi, InAlPSbBi, AlInGaP, AlInGaPSb, AlInGaPBi, AlInGaPSbBi, AlPSb, GaPSb, AlGaPSb, AlPBi, AlPSbBi, AlAsSb, AlAsBi, AlAsSbBi, AlN, AlNSb, AlNBi, or AlNSbBi.

Aspect 46. The method of any one of aspects 38 to 45, wherein the aluminum-containing barrier layer comprises InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi

Aspect 47. The method of any one of aspects 38 to 46, wherein the group V-containing layer comprises (In)GaAs.

Aspect 48. The method of any one of aspects 38 to 47, comprising, after depositing the group V-containing layer, depositing at least one second semiconductor layer over the high temperature barrier region.

Aspect 49. The method of aspect 48, further comprising, after depositing the at least one second semiconductor layer, thermally annealing the semiconductor structure at a temperature within a range from 600° C. to 900° C. for a duration from 5 seconds to 8 hours.

Aspect 50. The method of any one of aspects 48 to 49, wherein the at least one second semiconductor layer comprises a dilute nitride.

Aspect 51. A method of fabricating a semiconductor device, comprising; providing the semiconductor structure of any one of aspects 1 to 33; and depositing at least one third semiconductor layer on the second semiconductor layer to form a semiconductor device.

Aspect 52. The method of aspect 51, wherein the semiconductor device comprises a multijunction solar cell.

Aspect 53. The method of any one of aspects 51 to 52, wherein the at least on third semiconductor layer comprises at least one dilute nitride junction.

Aspect 54. The method of any one of aspects 51 to 53, wherein the first semiconductor layer comprises an n-p (Si,Sn)Ge junction.

Aspect 55. A multijunction photovoltaic cell, comprising: an n-p (Sn,Si)Ge junction comprising an arsenic-doped n-type region; an high-temperature barrier region overlying the n-type region of the n-p (Sn,Si)Ge junction, wherein the high-temperature barrier region comprises one or more barrier layers, wherein at least one of the barrier layers comprises an indium-free barrier layer or an aluminum-containing barrier layer; an (In)GaAs layer overlying the high-temperature barrier region; and at least one dilute nitride junction overlying the (In)GaAs layer.

Aspect 56. The multijunction photovoltaic cell of aspect 55, wherein the indium-free barrier layer comprises AlP, GaP, AlGaP, AlPSb, GaPSb, or AlGaPSb.

Aspect 57. The multijunction photovoltaic cell of any one of aspects 55 to 56, wherein the high-temperature barrier region comprises:indium-free barrier layer; and a second barrier layer overlying the indium-free barrier layer, wherein the second barrier layer comprises InAlP, InGaP, AlGaP, AlP, GaP, InAlPSb, InAlPBi, InAlPSbBi, AlInGaP, AlInGaPSb, AlInGaPBi, AlInGaPSbBi, AlPSb, GaPSb, AlGaPSb, AlPBi, AlPSbBi, AlAsSb, AlAsBi, AlAsSbBi, AlN, AlNSb, AlNBi, or AlNSbBi.

Aspect 58. The multijunction photovoltaic cell of any one of aspects 55 to 57, wherein the aluminum-containing barrier layer comprises InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi.

Aspect 59. The multijunction photovoltaic cell of any one of aspects 55 to 58, wherein, the high-temperature barrier region comprises an AlP layer and an InGaAlPSb layer overlying the AlP layer, wherein the InGaAlPSb layer comprises InGaAlP_{1-z}Sb_{z}, wherein 0≤z≤0.38.

Aspect 60. The multijunction photovoltaic cell of any one of aspects 55 to 59, wherein the high-temperature barrier region comprises an InAlPSb layer, wherein the InAlPSb layer comprises InAlP_{1-z}Sb_{z}, wherein 0≤z≤0.34.

Aspect 61. The multijunction photovoltaic cell of any one of aspects 55 to 60, wherein the at least one dilute nitride junction is lattice matched to the n-p (Sn,Si)Ge junction.

Aspect 62. The multijunction photovoltaic cell of any one of aspects 55 to 61, wherein the at least one dilute nitride junction comprises GaInNAsSb, GaInNAsBi, GaInNAsSbBi, GaNAsSb, GaNAsBi, or GaNAsSbBi.

Aspect 63. The multijunction photovoltaic cell of any one of aspects 55 to 62, wherein the n-p (Sn,Ge) junction, the high-temperature barrier region, the (In)GaAs layer, and the at least one dilute nitride junction were exposed to thermal annealing at a temperature within a range from 600° C. to 900° C. for a duration from 5 seconds to 8 hours.

Aspect 64. The multijunction photovoltaic cell of any one of aspects 55 to 63, wherein the high-temperature barrier region has a thickness from 0.25 nm to 200 nm.

Aspect 65. The multijunction photovoltaic cell of any one of aspects 55 to 64, wherein each of the one or more barrier layers independently has a thickness from 0.25 nm to 200 nm.

Aspect 66. A photovoltaic module comprising the multijunction photovoltaic cell of any one of aspects 55 to 65.

Aspect 67. A power system comprising the photovoltaic module of aspect 66.

It should be noted that there are alternative ways of implementing the embodiments disclosed herein. Accordingly, the present embodiments are to be considered as illustrative and not restrictive. Furthermore, the claims are not to be limited to the details given herein and are entitled their full scope and equivalents thereof

What is claimed is:

1. A semiconductor structure comprising:
a first semiconductor layer, wherein the first semiconductor layer comprises a group V element;
a high-temperature barrier region underlying the first semiconductor layer, wherein the high-temperature barrier region comprises one or more barrier layers, wherein at least one of the barrier layers comprises an indium-free barrier layer or an aluminum-containing barrier layer; and
a second semiconductor layer underlying the high-temperature barrier region.

2. The semiconductor structure of claim 1, wherein the group V element comprises arsenic.

3. The semiconductor structure of claim 1, wherein the first semiconductor layer comprises (In)AlGaAs or (In)GaAs.

4. The semiconductor structure of claim 1, wherein,
the indium-free barrier layer comprises AlP, GaP, AlGaP, AlPSb, GaPSb, or AlGaPSb; and
the aluminum-containing barrier layer comprises InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi.

5. The semiconductor structure of claim 1,
wherein the first barrier layer comprises an indium-free barrier layer; and
further comprising a second barrier layer overlying the indium-free barrier layer, wherein the second barrier layer comprises InAlP, InGaP, AlGaP, AlP, GaP, InAlPSb, InAlPBi, InAlPSbBi, AlInGaP, AlInGaPSb, AlInGaPBi, AlInGaPSbBi, AlPSb, GaPSb, AlGaPSb, AlPBi, AlPSbBi, AlAsSb, AlAsBi, AlAsSbBi, AlN, AlNSb, AlNBi, or AlNSbBi.

6. The semiconductor structure of claim 1, wherein,
the high-temperature barrier region comprises an aluminum/phosphorous-containing barrier layer; and
the aluminum/phosphorous-containing barrier layer comprises InAlP, InAlPSb, InAlPBi, InAlPSbBi, AlInGaP, AlInGaPSb, AlInGaPBi, AlInGaPSbBi, AlP, AlPSb, AlPBi, or AlPSbBi.

7. The semiconductor structure of claim 1, wherein the second semiconductor layer comprises (Si,Sn)Ge, Ge, or an n-p germanium junction.

8. The semiconductor structure of claim 1, wherein,
the first semiconductor layer comprises (In)GaAs;
the high-temperature barrier region comprises:
an AlP layer and an InGaAlPSb layer overlying the AlP layer, wherein the InGaAlPSb layer comprises InGaAlP_{1-z}Sb_{z}, wherein 0≤z≤0.38; or
a InAlPSb layer, wherein the InAlPSb layer comprises InAlP_{1-z}Sb_{z}, wherein 0≤z≤0.34; and
the second semiconductor layer comprises an n-p (Si,Sn)Ge junction.

9. The semiconductor structure of claim 1, further comprising at least one third semiconductor layer overlying the first semiconductor layer, wherein the at least one third semiconductor layer comprises a dilute nitride.

10. A semiconductor device comprising the semiconductor structure of claim 1.

11. A method of fabricating a semiconductor structure, comprising:
depositing a high-temperature barrier region on a first semiconductor layer, wherein the high-temperature barrier region comprises one or more barrier layers, wherein at least one of the barrier layers comprises an indium-free barrier layer or an aluminum-containing barrier layer; and
depositing a group V-containing layer on the high-temperature barrier region to form a semiconductor structure.

12. The method of claim 11,
wherein the first semiconductor layer comprises a p-type semiconductor; and
further comprising, depositing a high-temperature barrier region, forming an n-type region in the p-type semiconductor by exposing the p-type semiconductor to a gas phase n-type dopant to form a n-p junction,
wherein depositing a high-temperature barrier region comprises depositing the high-temperature barrier region on the n-type region.

13. The method of claim 12, wherein:
the n-type dopant comprises arsenic; and
the first semiconductor layer comprises an n-p junction.

14. The method of claim 11, further comprising, after depositing the group V-containing layer, thermally annealing the semiconductor structure at a temperature within a range from 600° C. to 900° C. for a duration from 5 seconds to 8 hours.

15. The method of claim 11, wherein the first semiconductor layer comprises (Si,Sn)Ge.

16. The method of claim 11, wherein,
the indium-free barrier layer comprises AlP, GaP, AlGaP, AlPSb, GaPSb, or AlGaPSb; and
the aluminum-containing barrier layer comprises InAlP, InAlPSb, InAlPBi, InAlPSbBi, AlInGaP, AlInGaPSb, AlInGaPBi, AlInGaPSbBi, AlP, AlPSb, AlPBi, AlPSbBi, AlAsSb, AlAsBi, AlAsSbBi, AlN, AlNSb, AlNBi, or AlNSbBi.

17. The method of claim 11, wherein the group V-containing layer comprises (In)GaAs.

18. The method of claim 11, comprising, after depositing the group V-containing layer, depositing at least one second semiconductor layer over the high temperature barrier region, wherein the at least one second semiconductor layer comprises a dilute nitride.

19. The method of claim 18, further comprising, after depositing the at least one second semiconductor layer, thermally annealing the semiconductor structure at a temperature within a range from 600° C. to 900° C. for a duration from 5 seconds to 8 hours.

20. A semiconductor structure fabricated using the method of claim 11.
